(19) United States
(12) Patent Application Publication
(10) Pub. No.: US 2024/0244807 A1
(43) Pub. Date: Jul. 18, 2024

(54) ELECTRIC POWER CONVERTER

(71) Applicant: HITACHI ASTEMO, LTD., Hitachinaka-shi, Ibaraki (JP)

(72) Inventors: Takahiro ARAKI, Tokyo (JP); Takeshi TOKUYAMA, Tokyo (JP); Masahiro SEO, Tokyo (JP); Noriyuki MAEKAWA, Hitachinaka-shi (JP); Shigehisa AOYAGI, Hitachinaka-shi (JP)

(73) Assignee: HITACHI ASTEMO, LTD., Hitachinaka-shi, Ibaraki (JP)

(21) Appl. No.: 18/563,667

(22) PCT Filed: Mar. 2, 2022
(86) PCT No.: PCT/JP2022/008997

§ 371 Date: Nov. 22, 2023

(30) Foreign Application Priority Data
Jul. 14, 2021 (JP) 2021-116693

(51) Int. Cl. H05K 7/20; H02M 7/00; H05K 7/14

(52) U.S. Cl. CPC H05K 7/20927; H02M 7/003; H05K 7/14322

(57) ABSTRACT

An electric power converter includes: an inverter circuit including a plurality of switching elements; a first capacitor and a second capacitor connected in parallel with the inverter circuit; a control circuit unit that controls the inverter circuit; and a connection conductor portion that connects the first capacitor and the second capacitor, wherein a conductive member is disposed between the control circuit unit and the connection conductor portion.

### TECHNICAL FIELD

The present invention relates to an electric power converter.

### BACKGROUND ART

As a background art of the present invention, PTL 1 listed below discloses a configuration in which a control circuits (gate terminals) are arranged on the left and right in order to reduce a rapid current change (surge) at the time of switching.

### CITATION LIST

### Patent Literature

PTL 1: JP 2020-156310 A

### SUMMARY OF INVENTION

### Technical Problem

Based on the configuration of PTL 1, it is necessary to realize magnetic interference suppression while addressing downsizing as a customer request. Therefore, an object of the present invention is to provide an electric power converter that achieves both thickness reduction and reliability.

### Solution to Problem

An electric power converter includes: an inverter circuit including a plurality of switching elements; a first capacitor and a second capacitor connected in parallel with the inverter circuit; a control circuit unit that controls the inverter circuit; and a connection conductor portion that connects the first capacitor and the second capacitor, wherein a conductive member is disposed between the control circuit unit and the connection conductor portion.

### Advantageous Effects of Invention

According to the present invention, it is possible to provide an electric power converter that achieves both thickness reduction and reliability.

### BRIEF DESCRIPTION OF DRAWINGS

FIG. 1 is an overall perspective view of an electric power converter having a configuration of the present invention and a view of the electric power converter from which a housing cover is removed.

FIG. 2 is a circuit diagram of the electric power converter of FIG. 1 and a view for illustration of movement of a current on a main circuit.

FIG. 3 shows views for illustration of a configuration of a switching element of the electric power converter of FIG. 1.

FIG. 4 is a connection perspective view between the switching element of FIG. 3 and the main circuit board.

FIG. 5 is a cross-sectional view of the electric power converter of FIG. 1 according to a first embodiment of the present invention taken along line A-A.

FIG. 6 is a view for illustration of movement of a resonance current in FIG. 5.

FIG. 7 is a view for illustration of an induction current and a magnetic flux in FIG. 6.

FIG. 8 is a cross-sectional view of an electric power converter according to a second embodiment of the present invention.

FIG. 9 is a view in which a configuration of FIG. 8 is provided with a housing.

FIG. 10 is an upper cross-sectional view of an electric power converter according to a third embodiment of the present invention.

### DESCRIPTION OF EMBODIMENTS

Hereinafter, embodiments of the present invention will be described with reference to the drawings. The following description and drawings are examples for describing the present invention, and omission and simplification are made as appropriate for the sake of clarity of description. The present invention can be carried out in various other forms. Unless otherwise specified, each component may be singular or plural.

Positions, sizes, shapes, ranges, and the like of the components illustrated in the drawings may not represent actual positions, sizes, shapes, ranges, and the like in order to facilitate understanding of the invention. Therefore, the present invention is not necessarily limited to the positions, sizes, shapes, ranges, and the like disclosed in the drawings.

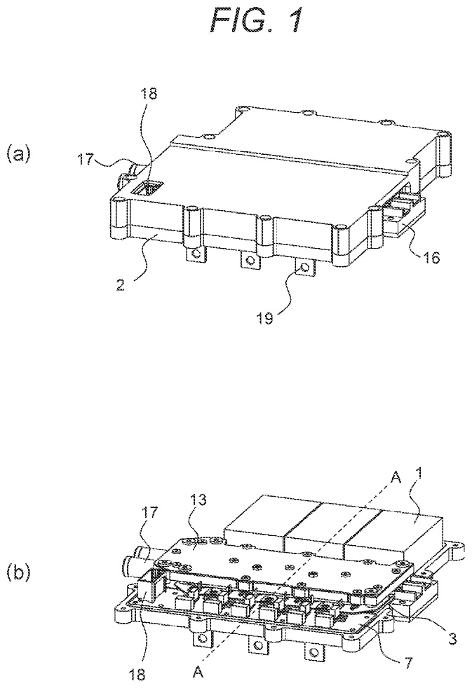

FIG. 1 is an overall perspective view of an electric power converter having a configuration of the present invention and a view of the electric power converter from which a housing cover is removed.

A housing 2 of the electric power converter includes a DC input terminal 16 that supplies a DC current to an inverter circuit provided inside the housing 2, an AC conductor 19 that outputs an AC current from the inverter circuit to an external motor (not illustrated), a refrigerant inflow port 17 that supplies a refrigerant for cooling the inverter circuit to the inside of the housing 2, and a control signal input/output terminal 18 that transmits a control signal of the inverter circuit to an external control device. A part of the control signal input/output terminal 18 protrudes from the housing 2 in order to be connected to a peripheral device of the housing 2. The housing 2 seals the inside to prevent a foreign matter and water from entering the inverter circuit from the outside. The housing 2 is made of aluminum, iron, or the like.

Inside the housing 2, a first capacitor 1 that is a capacitor for smoothing a DC current input from the DC input terminal 16, a main circuit unit 3 that converts a DC current into an AC current, a cooler 13 that is a refrigerant water path for cooling the main circuit unit 3, and a control circuit unit 7 that controls the inverter circuit based on a command input from an external control device are mounted.

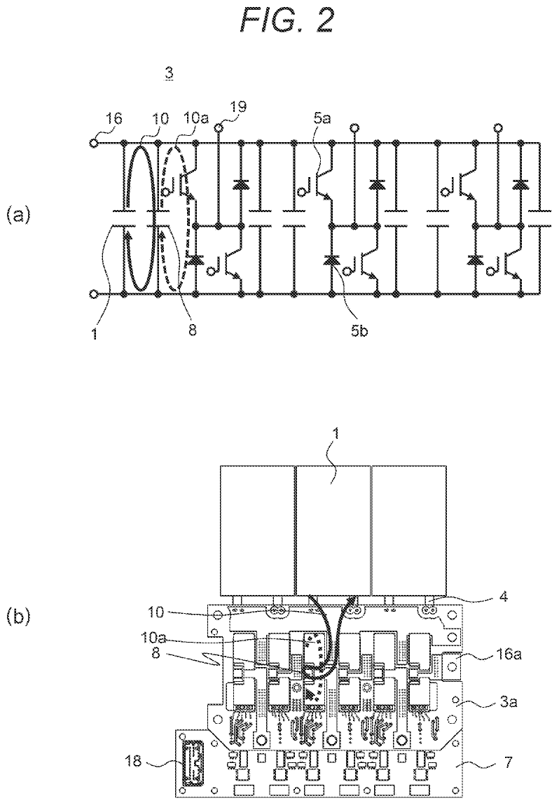

FIG. 2 is a circuit diagram of the electric power converter of FIG. 1 and a view for illustration of movement of a current on a main circuit.

The main circuit unit 3 of the inverter circuit includes the DC input terminal 16, a second capacitor 8, an IGBT element 5a, a diode element 5b, and the AC conductor 19. The first capacitor 1 is connected in parallel with a positive electrode and a negative electrode of the DC input terminal 16.

The IGBT element 5a is connected in series with the diode element 5b. The IGBT element 5a and the diode element 5b are connected in parallel with the second capacitor 8. The IGBT element 5a is turned on and off based on a signal from the control circuit unit 7, and thus converts a DC current into an AC current. By configuring the IGBT element 5a, the diode element 5b, and the second capacitor 8 as units for three phases, a three-phase inverter is constituted.

A transient current 10a such as a diode recovery current generated in accordance with on and off of the IGBT element 5a flows through a path from the second capacitor 8 indicated by a dotted line illustrated in the drawing.

In addition, a resonance current 10 generated due to wiring inductance of a connection conductor portion 4 connecting the first capacitor 1 and the second capacitor 8 and a main circuit wiring member 3a flows through a path indicated by a black thick line path illustrated in the drawing.

The first capacitor 1 is configured by a capacitor having a large capacitance such as a film capacitor, and constituted by an insulating resin covering the periphery and a terminal. The first capacitor 1 is connected to the DC input terminal 16 via the main circuit wiring member 3a.

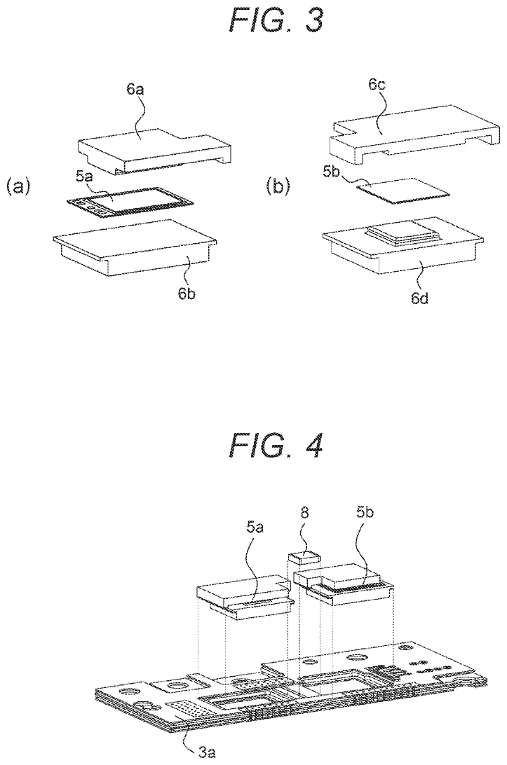

FIG. 3 shows views for illustration of a configuration of the switching element of the electric power converter of FIG. 1. FIG. 4 is a connection perspective view between the switching element of FIG. 3 and the main circuit board.

A first lead frame 6a is electrically connected to an upper surface of the IGBT element 5a, and a second lead frame 6b is electrically connected to a lower surface of the IGBT element 5a by a bonding member such as solder, and upper and lower surfaces of the IGBT element 5a are cooled by the cooler 13 described above. Terminals are provided at ends of the first lead frame 6a and the second lead frame 6b, respectively, and are electrically connected to the main circuit wiring member 3a by solder or the like. The main circuit wiring member 3a is a substrate on which each lead frame is mounted, and a printed circuit board, a copper bus bar, or the like is used.

A third lead frame 6c is electrically connected to an upper surface of the diode element 5b, and a fourth lead frame 6d is electrically connected to a lower surface of the diode element 5b by a bonding member such as solder, and upper and lower surfaces of the diode element 5b are cooled by the cooler 13 described later. Terminals are provided at ends of the third lead frame 6c and the fourth lead frame 6d, respectively, and are electrically connected to the main circuit wiring member 3a by solder or the like.

The second capacitor 8 is electrically connected to the IGBT element 5a and the diode element 5b via the main circuit wiring member 3a. The second capacitor 8 is disposed between the IGBT element 5a and the diode element 5b to decrease the path length of the wiring pattern of the main circuit wiring member 3a.

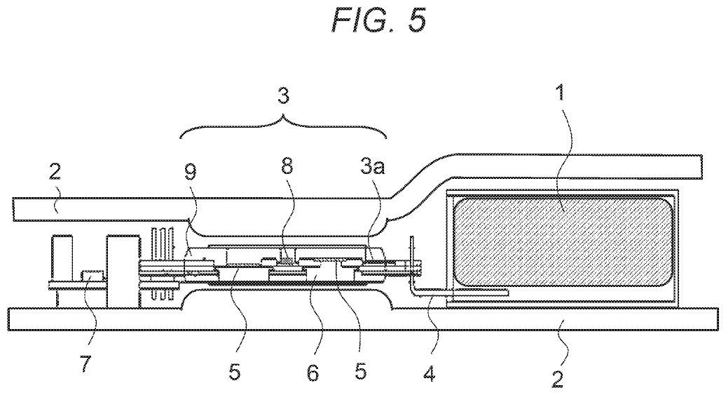

FIG. 5 is a cross-sectional view of the electric power converter of FIG. 1 according to a first embodiment of the present invention taken along line A-A.

The main circuit unit 3 includes a plurality of switching elements 5, the first capacitor 1, the second capacitor 8, the main circuit wiring member 3a, and a sealing resin 9. As each of the switching elements 5, the IGBT element 5a and the diode element 5b that are described above, a MOSFET element, and the like are used. A conductive member such as lead frame 6 (the first lead frame 6a to the fourth lead frame 6d described above in FIG. 3) is provided in the main circuit unit 3, and the switching element 5 and the lead frame 6 are electrically connected by a bonding material such as solder. The lead frame 6 is electrically connected to the main circuit wiring member 3a by soldering, welding, or the like.

The second capacitor 8 is configured by a small capacitor having excellent frequency characteristics, such as a ceramic capacitor, and supplies a transient current immediately after the switching element 5 is switched from on to off or from off to on. The second capacitor 8 is connected in parallel with the first capacitor 1, and is disposed at a position where wiring inductance between the IGBT element 5a and the diode element 5b is smaller than that of the first capacitor 1. The first capacitor 1 and the second capacitor 8 are connected in parallel with the inverter circuit.

The sealing resin 9 covers the first capacitor 1, the plurality of switching elements 5, the lead frame 6, and the main circuit wiring member 3a to suppress entering of a foreign matter into the main circuit unit 3.

A conductive member 2 is the same as the housing 2 illustrated in FIG. 1, and is made of aluminum, iron, copper, or the like. The conductive member 2 can also be used as a fixing member for the first capacitor 1, the main circuit unit 3, and the control circuit unit 7. The conductive member 2 can also improve heat dissipation performance by being brought into contact with a heat generating component such as the main circuit unit 3. The conductive member 2 includes an uneven shape around the second capacitor 8, the main circuit unit 3, and the control circuit unit 7, and around the first capacitor 1, according to a difference in height of these components. As a result, the conductive member 2 can be brought close to current paths respectively passing through the second capacitor 8, the main circuit unit 3, and the control circuit unit 7, and an effect of canceling a magnetic flux described later can be improved.

The control circuit unit 7 is connected to the switching elements 5 via a connector, the main circuit wiring member 3a, wire bonding, or the like, and controls on and off of the switching elements 5. The control circuit unit 7 is provided with a gate drive circuit that drives the gate of the switching elements 5, a motor control circuit that generates a gate signal according to a rotational speed and torque of the motor, a power supply circuit that supplies power necessary for an operation of each control circuit, and the like.

The connection conductor portion 4 is a terminal of the first capacitor 1 and is connected to the main circuit wiring member 3a. The resonance current 10 to be described later generated due to wiring inductance existing between the first capacitor 1 and the second capacitor 8 flows through the connection conductor portion 4.

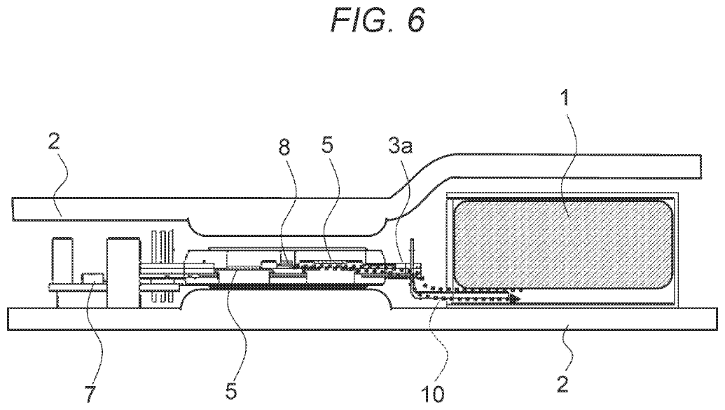

FIG. 6 is a view for illustration of movement of the resonance current in FIG. 5.

The second capacitor 8 is disposed in the vicinity of the switching element 5 in order to reduce wiring inductance of the current path constructed by the plurality of switching elements 5, and is connected in parallel with the first capacitor 1 via the main circuit wiring member 3a.

The first capacitor 1 supplies a steady current while the switching element 5 is on or off. At this time, since wiring inductance exists in an electric wiring connecting the first capacitor 1 and the second capacitor 8, the resonance current 10 is generated between the first capacitor 1 and the second capacitor 8.

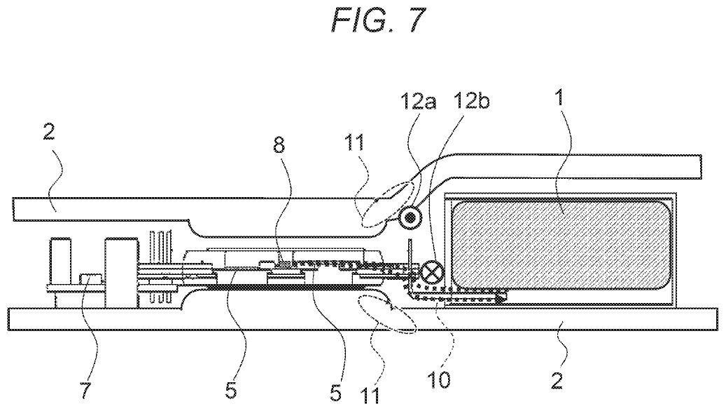

FIG. 7 is a view for illustration of an induction current and a magnetic flux in FIG. 6.

A part of the conductive member 2 is disposed between the connection conductor portion 4 connecting the first capacitor 1 and the second capacitor 8 and the control circuit unit 7. As a result, an induction current 11 is generated in the conductive member 2 due to the resonance current 10 flowing through the connection conductor portion 4. A magnetic flux 12b of the resonance current 10 is canceled by a magnetic flux 12a generated by the induction current 11. As a result, the magnetic flux 12b of the resonance current 10 flowing through the connection conductor portion 4 can be prevented from magnetically interfering with the control circuit unit 7. As a result, a stable operation of the control circuit unit 7 can be realized.

Similarly to the induction current 11 due to the resonance current 10, by the transient current 10a flowing between the switching element 5 and the second capacitor 8 in the main circuit wiring member 3a described above also generates an induction current in the conductive member 2 disposed opposite to the upper and the lower surfaces of the main circuit wiring member 3a. This induction current reduces wiring inductance of the path of the transient current 10a. Furthermore, leakage of the magnetic flux due to the transient current 10a is suppressed by the induction current generated in the conductive member 2.

### Second Embodiment

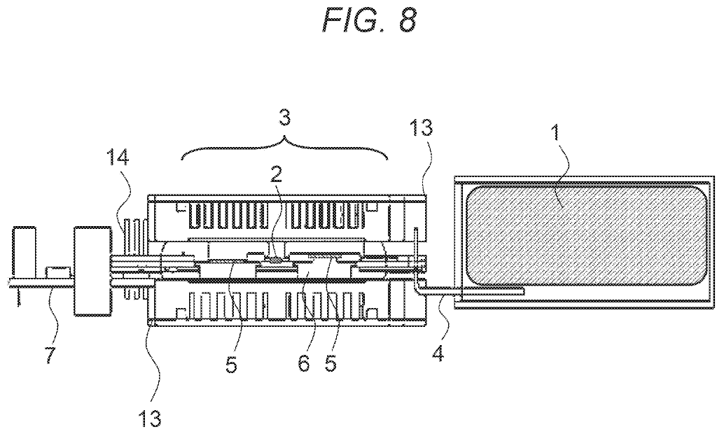

FIG. 8 is a cross-sectional view of an electric power converter according to a second embodiment of the present invention.

The cooler 13 is configured by a material having excellent thermal conductivity such as aluminum or copper, increases an area of a heat dissipation surface by providing fins, and can improve cooling performance by cooling air or cooling water supplied from the outside. The cooler 13 is provided on both upper and lower surfaces of the main circuit unit 3, so that cooling performance of the inverter circuit can be improved. The cooler 13 is in contact with the lead frame 6 via an insulation member. Heat dissipation grease or the like is applied to the insulation member in order to enhance adhesion between the lead frame 6 and the cooler 13. A gate terminal 14 is disposed on a side of the control circuit unit 7.

Thus, by providing the conductive cooler 13 above and below the inverter circuit, particularly above and below the switching element 5 having a large calorific value, not only the cooling performance of the inverter circuit can be improved and the size of the inverter circuit can be reduced, but also the magnetic flux of the resonance current can be canceled by the magnetic flux generated by the induction current caused by the resonance current flowing through the connection conductor portion 4 similarly to the conductive member 2 described above, and it is possible to suppress the magnetic interference between the control circuit unit 7 and the connection conductor portion 4.

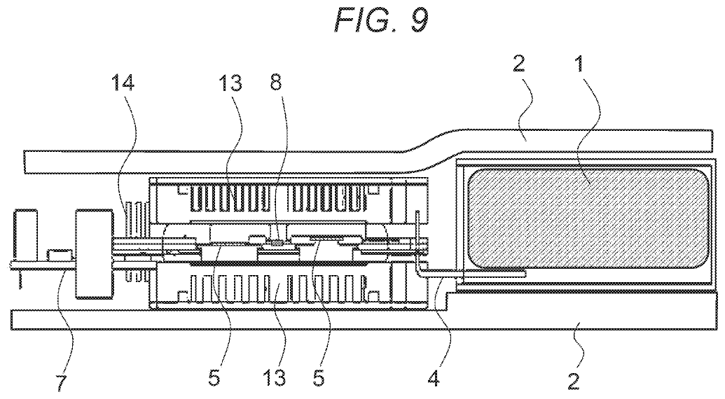

FIG. 9 is a view in which a configuration of FIG. 8 is provided with a housing.

The first capacitor 1, the cooler 13, the main circuit unit 3, and the control circuit unit 7 are fixed to a lower surface of the housing 2. The magnetic interference reduction effect can be further improved by disposing the housing 2 such that a gap between the housing 2 and the cooler 13 is narrowed. In addition, by bringing the housing 2 close to the connection conductor portion 4, wiring inductance can be reduced, and the resonance current described above can be suppressed. At this time, by providing an insulating heat dissipation member in a gap between the housing 2 and the connection conductor portion 4, cooling performance of the connection conductor portion 4 can be improved.

Further, by fixing the first capacitor 1 to the housing 2 via an insulating heat dissipation member, and fixing the cooler 13 to the housing 2 via a similar heat dissipation member, heat generated in the first capacitor 1 can be released to the refrigerant flowing into the cooler 13 via the housing 2. As a result, since the upper surface and the lower surface of the connection conductor portion 4 and the cooler 13 are covered with the conductive housing 2, the magnetic flux of the resonance current that cannot be canceled by the cooler 13 alone can be canceled by the magnetic flux of the induction current generated in the conductive housing 2.

### Third Embodiment

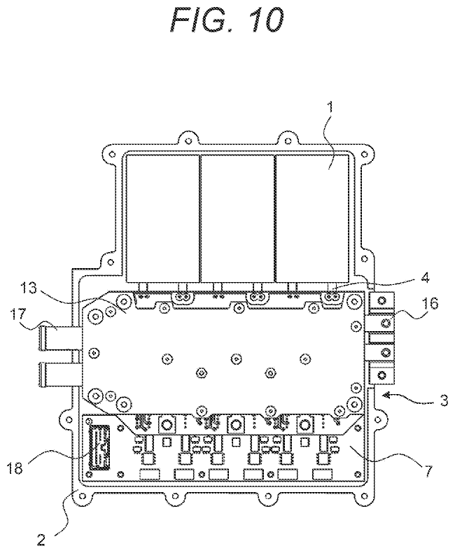

FIG. 10 is an upper cross-sectional view of an electric power converter according to a third embodiment of the present invention.

The refrigerant inflow port 17 provided in the housing 2 is connected to an external refrigerant supply device such as a fan or a pump, and a refrigerant such as cooling air, cooling water, or cooling oil is supplied into the housing 2. Further, the refrigerant inflow port 17 is connected to the cooler 13, and a connection point thereof is sealed by a seal member such as an O-ring. The refrigerant inflow port 17 is disposed at a right angle to a direction in which the first capacitor 1, the main circuit unit 3, and the control circuit unit 7 are arranged and on the side of the cooler 13. This makes it is possible to decrease the flow path length of the refrigerant while arrangement interference with other components such as the first capacitor 1 and the main circuit unit 3 is avoided. Furthermore, by disposing the refrigerant inflow port 17 on the side of the cooler 13, thickness of the entire cooling unit is reduced.

According to the first to the third embodiments of the present invention described above, the following effects and advantages are obtained.

(1) The electric power converter includes the inverter circuit including the plurality of switching elements, the first capacitor 1 and the second capacitor 8 connected in parallel with the inverter circuit, the control circuit unit 7 that controls the inverter circuit, and the connection conductor portion 4 that connects the first capacitor 1 and the second capacitor 8, wherein the conductive member 2 is disposed between the control circuit unit 7 and the connection conductor portion 4. With this configuration, it is possible to provide an electric power converter that achieves both thickness reduction and reliability.

(2) The conductive member 2 is the cooler 13 that cools the inverter circuit. In this way, not only improvement in the cooling performance and downsizing of the inverter circuit are realized, but also the magnetic flux of the resonance current is canceled by the magnetic flux generated by the induction current caused by the resonance current flowing through the connection conductor portion 4.

(3) In the electric power converter, the conductive member 2 is provided on the upper and lower surfaces of the connection conductor portion 4 and the cooler 13. In this way, the magnetic flux of the resonance current that cannot be canceled by the cooler 13 alone is canceled by the magnetic flux of the induction current generated in the conductive housing 2.

(4) In the electric power converter, the refrigerant inflow port 17 is provided on the side of the cooler 13. In this way, it is possible to decrease the flow path length of the refrigerant while arrangement interference with other components such as the first capacitor 1 and the main circuit unit 3 is avoided. Furthermore, by disposing the refrigerant inflow port 17 on the side of the cooler 13, thickness of the entire cooling unit is reduced.

Note that the present invention is not limited to the above embodiments, and various modifications and other configurations can be combined without departing from the gist of the present invention. In addition, the present invention is not limited to a case including all the configurations described in the above embodiments, and includes a case in which a part of the configurations is omitted.

### REFERENCE SIGNS LIST

1 first capacitor
2 housing (conductive member)
3 main circuit unit
3a main circuit wiring member
4 connection conductor portion
5 switching element
5a IGBT element
5b diode element
6 lead frame
6a first lead frame
6b second lead frame
6c third lead frame
6d fourth lead frame
7 control circuit unit
8 second capacitor
9 sealing resin
10 resonance current
10a transient current
11 induction current
12a magnetic flux (induction current side)
12b magnetic flux (resonance current side)
13 cooler
14 gate terminal
16 DC input terminal
16a DC input terminal connecting portion
17 refrigerant inflow port
18 control signal input/output terminal
19 AC conductor

1. An electric power converter comprising:
an inverter circuit including a plurality of switching elements;
a first capacitor and a second capacitor connected in parallel with the inverter circuit;
a control circuit unit that controls the inverter circuit; and
a connection conductor portion that connects the first capacitor and the second capacitor, wherein
a conductive member is disposed between the control circuit unit and the connection conductor portion.

2. The electric power converter according to claim 1, wherein
the conductive member is a cooler that cools the inverter circuit.

3. The electric power converter according to claim 2, wherein
the conductive member is provided on upper and lower surfaces of the connection conductor portion and the cooler.

4. The electric power converter according to claim 2, wherein
a refrigerant inflow port is provided on a side of the cooler.
